(19) United States
(12) Patent Application Publication
(10) Pub. No.: US 2002/0068446 A1
(43) Pub. Date: Jun. 6, 2002

(54) Method of forming self-aligned silicide layer

(76) Inventors: Yi-Ju Wu, Taichung (TW); Yu Chung Chang, Taichung Hsien (TW); Brian Wang, Taoyuan Hsien (TW)

Correspondence Address: CHARLES C.H. WU & ASSOCIATES, Suite 710, 7700 IRVINE CENTER DRIVE, Irvine, CA, 92618-3043, US

(21) Appl. No.: 09/708,781

(22) Filed: Dec. 14, 2000

(30) Foreign Application Priority Data
Dec. 4, 2000 (TW) 89125785

(51) Int. Cl. H01L 21/336

(52) U.S. Cl. 438/664; 438/299

(57) ABSTRACT

A method of forming a self-aligned silicide layer. A refractory metal layer is formed over a substrate having a metal-oxide-semiconductor (MOS) transistor thereon. A self-aligned silicide reaction is conducted to form a self-aligned silicide layer over the gate electrode and source/drain terminal of the transistor. Finally, the unreacted refractory metal layer and the protective layer are removed. The method also includes the formation of an additional protective layer between the refractory metal layer and the original protective layer by physical vapor deposition before conducting the self-aligned silicide reaction.

### CROSS-REFERENCE TO RELATED APPLICATION

This application claims the priority benefit of Taiwan application serial no. 89125785, filed Dec. 4, 2000.

### BACKGROUND OF THE INVENTION

1. Field of Invention

The present invention relates to a method of manufacturing a metal-oxide-semiconductor (MOS) transistor. More particularly, the present invention relates to a method of forming a self-aligned silicide layer.

2. Description of Related Art

Following the increase in level of integration, pattern and line width of each semiconductor device is reduced leading to a higher contact resistance in its gate terminal and conductive wire. The higher contact resistance results in a longer resistance-capacitance (RC) delay that limits the operating speed of the device. Metal silicide material has resistance much lower than polysilicon and has heat stability much higher than most interconnect materials (for example, aluminum). Hence, a metal silicide layer is often formed over the gate terminal and the source/drain terminal. The metal silicide layer is able to lower the sheet resistance at the source/drain terminal and ensure integrity of the shallow junction between a metallic layer and the semiconductor device. Conventionally, a metal silicide layer is formed by depositing metal over a silicon material layer and then conducting a thermal reaction to initiate the reaction between the metal and the silicon to form the metal silicide. Alternatively, metal silicide material is directly deposited over a silicon material layer. At present, most semiconductor manufacturers employ a self-aligned silicide process to form metal silicide layers.

To form a self-aligned silicide layer, a metallic layer is formed over a semiconductor chip. The most commonly deployed metallic elements include cobalt and titanium. The semiconductor chip is next placed inside a chamber and heated to a high temperature so that the metal over the gate terminal and the source/drain terminal can react with silicon to form a silicide layer. The silicide layer also undergoes a phase transformation at high temperature to form a low resistant metal silicide layer. Since regions having metal in direct contact with silicon will react to form a silicide layer, no silicide layers are formed outside the source/drain terminals and the gate terminals. Because the silicide layers are formed in desired positions without carrying out a photolithographic process, this method of forming the metal silicide layers is called a self-aligned silicide process.

FIGS. 1A through 1C are schematic cross-sectional views showing the progression of steps for forming a conventional self-aligned silicide layer. As shown in FIG. 1A, a substrate 100 having a gate oxide layer 102, a gate electrode 104, source/drain terminals 106 and spacers 108 is provided. A cobalt layer 110 is formed over the substrate 100. As shown in FIG. 1B, a titanium nitride layer 112 that serves as a protective layer is formed over the cobalt layer 110 by physical vapor deposition (PVD). As shown in FIG. 1C, rapid thermal processing (RTP) is conducted to initiate the reaction between the cobalt in the cobalt layer 110 and the polysilicon in the gate electrode 104 and the silicon in the source/drain terminals 106. Ultimately, self-aligned cobalt silicide layers 114 are formed over the gate electrode 104 and the source/drain terminals 106. Finally, a wet etching process is carried out to remove the titanium nitride layer 112 as well as other unreacted cobalt material.

However, the process of forming a PVD titanium nitride layer over the cobalt layer may cause the diffusion of some oxygen into the titanium nitride layer. FIG. 2 is a schematic cross-sectional view showing two protective layers over a metallic layer in a conventional self-aligned silicide process. As shown in FIG. 2, a substrate 100 having a cobalt layer 110 thereon is provided. A titanium nitride layer 116 is formed over the cobalt layer 110 by physical vapor deposition (PVD). A titanium layer is formed over the titanium nitride layer 116 by PVD to serve as a second protective layer 118. Thereafter, subsequent processes for forming a self-aligned silicide layer are conducted.

The aforementioned processes of forming the self-aligned silicide layers have some drawbacks. The titanium nitride formed by physical vapor deposition has a columnar crystal structure. Before thermal treatment of the semiconductor devices, oxygen in the atmosphere may migrate along the crystal edges of the titanium nitride layer, pass through the cobalt layer and enter the polysilicon gate or the source/drain region to form oxide. Consequently, integrity of the cobalt, polysilicon or the substrate surface layer may be broken leading to possible junction leakage at the semiconductor surface.

To prevent the formation of oxides, idling time has to be reduced. In other words, the substrate containing the semiconductor devices must be transferred into a furnace for treatment immediately after the titanium nitride layer is formed. However, timing of the processing is rather stringent and difficult to control. Similarly, although adding one more titanium layer to serve as an oxygen barrier can block out most of oxygen, some oxygen can still penetrate through the barrier contributing to subsequent junction leakage problems.

Furthermore, if too high a temperature is used in rapid thermal processing, titanium may diffuse into the cobalt layer via the titanium nitride layer. The titanium may react with cobalt to form a compound that attaches to the spacers. The compound is difficult to remove in subsequent etching process so that bridging between a gate electrode and a neighboring source/drain terminal is possible. Hence, reliability of the semiconductor device is compromised.

### SUMMARY OF THE INVENTION

Accordingly, one object of the present invention is to provide a method of forming a self-aligned silicide layer capable of preventing oxide material from forming near the junction between a metallic layer and a gate electrode or the metallic layer and the source/drain region of a substrate. Hence, the possibility of junction leakage is minimized.

A second object of this invention is to provide a method of forming a self-aligned silicide layer capable of forming a thicker metal silicide layer so that resistance at the source/drain terminal is further reduced.

A third object of this invention is to provide a method of forming a self-aligned silicide layer such that exposure to atmosphere poses little or no adverse effect on the ultimately formed semiconductor devices. This makes the process timing much easier.

A fourth object of this invention is to provide a method of forming a self-aligned silicide layer capable of maintaining a vacuum between the metallic layer and the environment for depositing a protective layer. Hence, the production of natural oxide material is prevented.

A fifth object of this invention is to provide a method of forming a self-aligned silicide layer that permits an increase in rapid thermal processing temperature. Hence, a denser self-aligned silicide layer with a lower resistance is formed.

To achieve these and other advantages and in accordance with the purpose of the invention, as embodied and broadly described herein, the invention provides a method of forming a self-aligned silicide layer. First, a substrate is provided. A gate electrode is formed over the substrate and a source/drain region is formed in the substrate on each side of the gate electrode. A refractory metal layer is formed over the substrate. A protective layer having a thickness of between 100 Å to 200 Å is formed over the refractory metal layer by chemical vapor deposition (CVD). Rapid thermal processing is conducted to form a self-aligned silicide layer. Finally, a wet etching process is carried out to remove the unreacted refractory metal and the protective layer.

This invention also provides an alternative method of forming a self-aligned silicide layer. First, a substrate is provided. A gate electrode is formed over the substrate and a source/drain region is formed in the substrate on each side of the gate electrode. A refractory metal layer is formed over the substrate. A first protective layer having a thickness of between 100 Å to 200 Å is formed over the refractory metal layer by chemical vapor deposition (CVD). Similarly, a second protective layer having a thickness of between 100 Å to 200 Å is formed over the first protective layer by chemical vapor deposition (CVD). Rapid thermal processing is conducted to form a self-aligned silicide layer. Finally, a wet etching process is carried out to remove the unreacted refractory metal, the first protective layer and the second protective layer.

According to the embodiment, one major aspect of this invention is the formation of a protective layer over a cobalt layer by chemical vapor deposition. The CVD protection layer has an amorphous structure. The CVD protective layer is able to prevent oxygen in atmosphere from diffusing through the cobalt layer to form an oxide layer on the polysilicon gate or substrate surface of the source/drain before an annealing process. Hence, junction leakage caused by oxide damages near the contact region between the cobalt layer and the polysilicon or substrate is prevented.

Also, the CVD protection layer is capable of preventing the formation of oxide material at the contact surface between the cobalt layer and the polysilicon layer or the substrate. Consequently, a thicker cobalt silicide layer for lowering the resistance at the source/drain terminals is formed.

The CVD protection layer can effectively stop the diffusion of oxygen into the cobalt layer. Thus, the semiconductor device no longer has to be transferred into a reaction chamber immediately after the formation of the CVD protection layer. As a result, timing restriction for exposure to atmosphere is relieved. This makes control of the process timing easier.

As both the cobalt layer and the protective layer are formed in the same reaction chamber, the process is carried out in the chamber without exposing to the air. This further prevents a possible growth of natural oxide.

Furthermore, a CVD protective layer instead of a titanium layer is used as a second protective layer. This prevent the diffusion of titanium atoms through a PVD nitride layer into the cobalt layer resulted from a high temperature in RTP, since the diffused titanium atoms can react with the cobalt layer to form a compound adhered to the spacer, leading to a bridging between the gate and the source/drain terminal. Hence, when the diffusion of the titanium atoms is blocked, the bridging between the gate and the source/drain terminal is prevented. Ultimately, a larger process window for the rapid thermal processing temperature is granted and a denser self-aligned silicide layer with a lower resistance is obtained.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic cross-sectional views showing the progression of steps for forming a conventional self-aligned silicide layer;

FIG. 2 is a schematic cross-sectional view showing two protective layers over a metallic layer in a conventional self-aligned silicide process;

FIGS. 3A through 3D are schematic cross-sectional views showing the progression of steps for forming a self-aligned silicide layer according to one preferred embodiment of this invention; and

FIG. 4 is a schematic cross-sectional view showing two protective layers over a metallic layer according to another self-aligned silicide process of this invention.

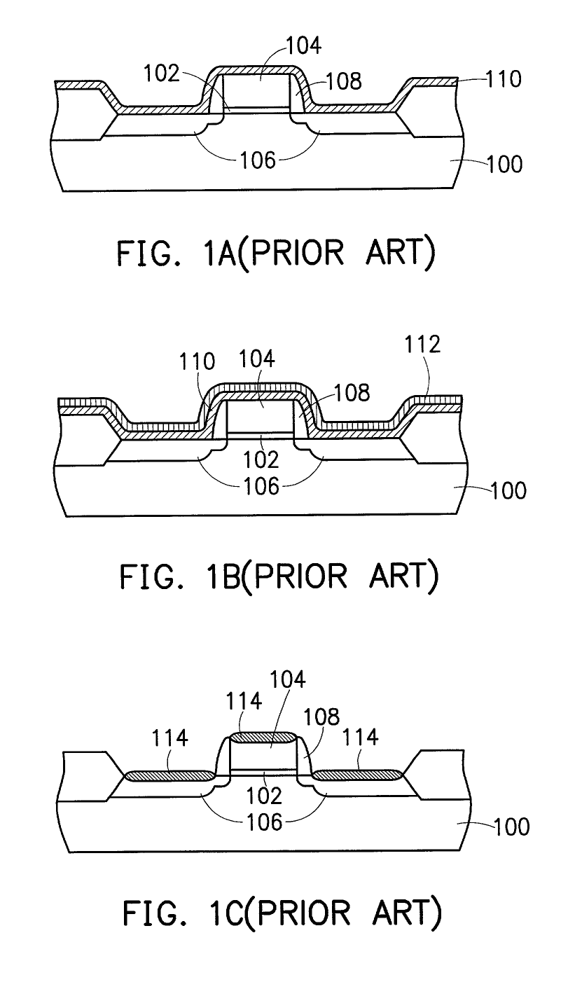

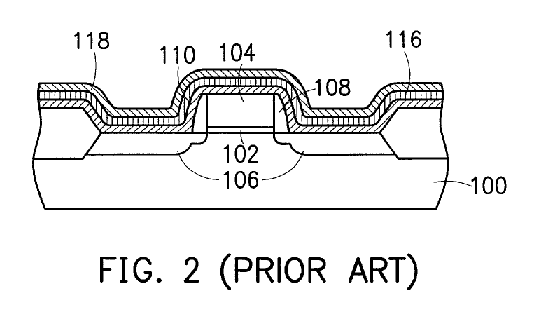

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

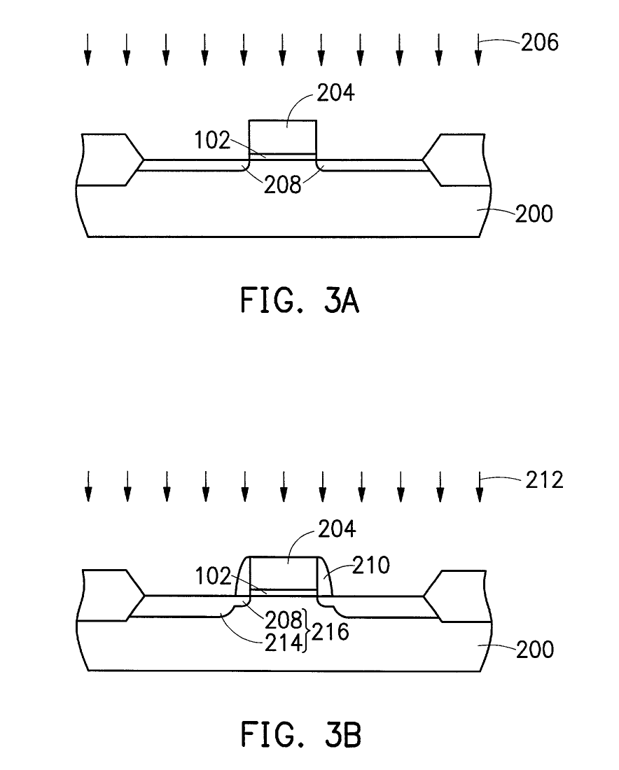

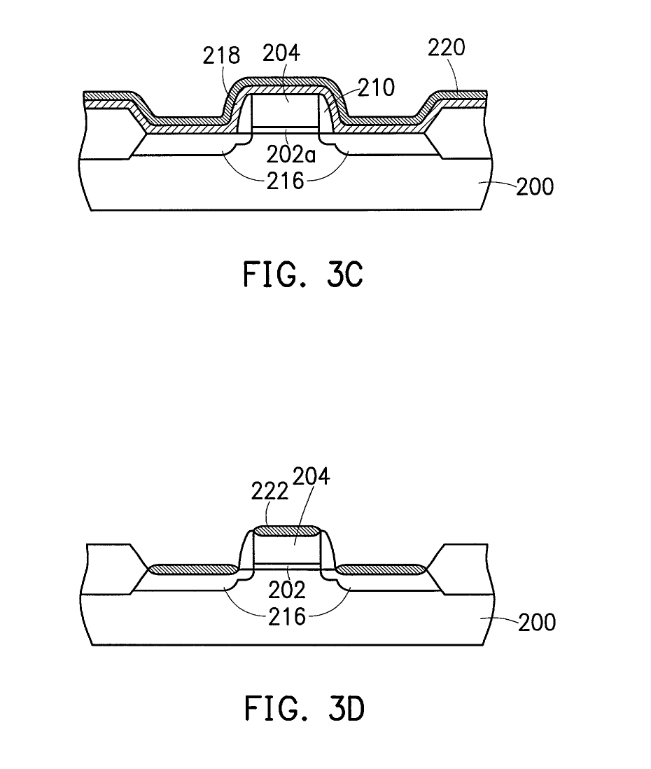

FIGS. 3A through 3D are schematic cross-sectional views showing the progression of steps for forming a self-aligned silicide layer according to one preferred embodiment of this invention.

As shown in FIG. 3A, a substrate 200 having a gate oxide layer 202 and a gate electrode 204 thereon is provided. An ion implantation 206 is carried out to form a lightly doped source/drain region 208 in the substrate 200 on each side of the gate electrode 204.

As shown in FIG. 3B, a conformal insulation layer (not shown) is formed over the substrate 200. The insulation layer can be a silicon oxide layer or a silicon nitride layer. The silicon oxide layer can be a tetra-ethyl-ortho-silicate (TEOS) layer formed, for example, by low-pressure chemical vapor deposition. A portion of the insulation layer is removed to form spacers 210 on the sidewalls of the gate electrode 204 while exposing the upper surface of the gate electrode 204 and a portion of the substrate 200. The step of removing a portion of the insulation layer includes performing an anisotropic etching operation. An ion implantation 212 is carried out to form a heavily doped source/drain region 214 using the gate electrode 204 and the spacers 210 as a mask. The lightly doped source/drain region 208 and the heavily doped source drain region 214 together form a source/drain region 216.

As shown in FIG. 3C, a refractory metal layer 218 is formed over the substrate 200 covering the source/drain region 216, the gate electrode 204 and the spacers 210. The refractory metal layer can be a cobalt layer formed, for example, by sputtering such as a DC magnetron sputtering method. A protective layer 220 having a thickness between about 100 Å to 200 Å is formed over the metallic layer 218. The protective layer 220 can be formed, for example, by chemical vapor deposition (CVD). Material constituting the protective layer 220 includes titanium nitride. Since a sputtering chamber can be incorporated with a chemical vapor deposition chamber, the processing chip can remain unexposed to the air. In other words, both the metallic layer 218 and the protective layer 220 are formed inside the same reaction chamber. Consequently, no natural oxide will grow the surface of the metallic layer 218. Because the protective layer 220 is formed by chemical vapor deposition (CVD), the protective layer 220 has an amorphous structure. The amorphous structure is capable of stopping diffusion of oxygen through the metallic layer 218 into the polysilicon layer. Therefore, this stops diffused oxygen from reacting with metallic layer and polysilicon layer for forming the oxides. Accordingly, the semiconductor device is prevented from producing the leakage current.

As shown in FIG. 3D, a thermal treatment is carried out so that metal in the metallic layer 218 reacts with polysilicon in the gate electrode 204 and silicon in the source/drain region 216 to form a self-aligned silicide layer 222. The thermal treatment includes rapid thermal process. The protective layer 220 and unreacted metallic layer 218 are removed to expose the self-aligned silicide layer 222 and the spacers 210. The step of removing the protective layer 220 and the unreacted metallic layer 218 includes wet etching. Finally, a post thermal treatment is conducted to densify the self-aligned silicide layer 222 lying over the source/drain region 216 and the gate electrode 204. Therefore, the self-aligned silicide layer 222 can have a lower electrical resistance. Similarly, the post thermal treatment may be rapid thermal process.

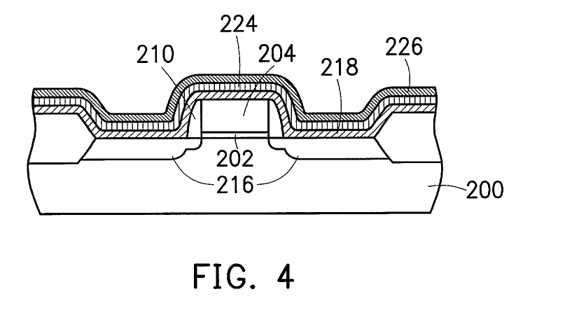

FIG. 4 is a schematic cross-sectional view showing two protective layers over a metallic layer according to another self-aligned silicide process of this invention. First, as shown in FIGS. 3A and 3B, a gate oxide layer 202, a gate electrode 204, spacers 210 and source/drain regions 216 are formed over a substrate 200. A metallic layer 218 is formed over the substrate 200 covering the source/drain regions 216, the gate electrode 204 and the spacers 210. Thereafter, a first protective layer 224 having a thickness of between about 100 to 200 is formed over the metallic layer 218, for example, by physical vapor deposition (PVD). The first protective layer 224 can be a titanium nitride layer, for example. A second protective layer 226 having a thickness of between about 100 to 200 is formed over the first protective layer 224, for example, by chemical vapor deposition (CVD). Since a sputtering chamber can be incorporated with a chemical vapor deposition chamber, the processing chip can remain unexposed to the air. Accordingly, the metallic layer 218, the first protective layer 224 and the second protective layer 226 are formed inside the same processing station. Because the first protective layer 224 is formed by physical vapor deposition, the titanium nitride layer has a high purity. The high-purity titanium layer is capable of preventing carbon or any impurities inside the second protective layer 226 from attaching to the spacers 210. In addition, since the second protective layer 226 is formed by chemical vapor deposition, the second protective layer 226 has an amorphous structure. The second protective layer 226 is capable of blocking the diffusion of oxygen which reacts with polysilicon to form oxides.

Finally, as shown in FIG. 3D, a thermal treatment is carried out so that metal in the metallic layer 218 reacts with polysilicon in the gate electrode 204 and silicon in the source/drain region 216 to form a self-aligned silicide layer 222. The thermal treatment includes rapid thermal process. The first protective layer 224, the second protective layer 226 and unreacted metallic layer 218 are removed to expose the self-aligned silicide layer 222 and the spacers 210. The step of removing the protective layer 220 and the unreacted metallic layer 218 includes wet etching. Lastly, a post thermal treatment is conducted to densify the self-aligned silicide layer 222 lying over the source/drain region 216 and the gate electrode 204. Therefore, the self-aligned silicide layer 222 can have a lower electrical resistance. Similarly, the post thermal treatment includes rapid thermal process.

According to the embodiment, one major aspect of this invention is the formation of a CVD protective layer having an amorphous structure over the metallic layer. The CVD protective layer is able to prevent oxygen from diffusing through the metallic layer for forming an oxide layer on the polysilicon gate or the substrate surface of the source/drain before the annealing process. Hence, junction leakage caused by oxide formations near the contact region between the metallic layer and the polysilicon or the substrate is prevented.

Since the CVD protection layer is capable of preventing the formation of the oxide at the contact surface between metal and polysilicon or silicon substrate. Consequently, a thicker metal silicide layer for lowering the resistance of the source/drain terminal is formed.

In addition, the CVD protection layer can stop the diffusion of oxygen atoms quite effectively. Therefore, the semiconductor device no longer has to be transferred into a reaction chamber immediately after the formation of the CVD protection layer. Consequently, restriction for exposure to atmosphere is relieved. This makes control of processing timing easier.

Because both the metallic layer and the protective layer are formed inside the same reaction chamber, the processing chip can remain unexposed to the air. Hence, the probability of forming a natural oxide layer inside the silicon chip is further reduced.

Furthermore, the use of a CVD protective layer instead of a titanium layer as a second protective layer can prevent the diffusion of titanium atoms through a PVD nitride layer into the metallic layer to form a compound near the spacers in high temperature RTP. Hence, bridging between the gate and the source/drain terminal is prevented. Ultimately, a larger process window for the rapid thermal processing temperature is allowed and a denser self-aligned silicide layer with a lower resistance can be obtained.

In conclusion, the CVD protection layer in this invention facilitates the self-aligned silicide process, so the silicide layer having a good adhesion with the gate electrodes and the source/drain terminals is formed. Thus, there is no time restriction in transfering the semi-finished product. In addition, a thicker silicide layer may be formed and a higher rapid thermal processing temperature range may be used to densify the self-aligned silicide layer. Ultimately, a lower silicide resistance and a higher production yield can be obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a self-aligned silicide layer, comprising the steps of:
providing a substrate having a gate electrode, a spacer and a source/drain region thereon;
forming a cobalt layer that covers the source/drain region, the gate electrode and the spacers above the substrate;
forming a protective layer over the source/drain region, the gate electrode and the spacer by chemical vapor deposition;
conducting a thermal treatment to form a cobalt silicide layer at the junctions between the metallic layer and the source/drain region and the gate electrode; and
removing the protective layer and the unreacted cobalt layer.

2. The method of claim 1, wherein the step of forming the protective layer includes depositing titanium nitride.

3. The method of claim 1, wherein the protective layer has a thickness between about 100 Å to 200 Å.

4. The method of claim 1, wherein the step of forming a cobalt layer includes physical vapor deposition (PVD).

5. The method of claim 1, wherein the step of forming the cobalt layer includes performing a DC magnetron sputtering.

6. The method of claim 1, wherein the metallic layer and the protective layer are formed in the same reaction chamber.

7. The method of claim 1, wherein the thermal treatment includes a rapid thermal process.

8. The method of claim 1, wherein after the step of removing the protective layer and the unreacted cobalt layer, further includes performing a post thermal treatment.

9. The method of claim 8, wherein the post thermal treatment includes a rapid thermal process.

10. A method of forming self-aligned silicide layer, comprising the steps of:
providing a substrate having a gate electrode, a spacer and a source/drain region thereon;
forming a metallic layer that covers the source/drain region, the gate electrode and the spacer above the substrate;
forming a first protective layer over the metallic layer by physical vapor deposition;
forming a second protective layer over the first protective layer by chemical vapor deposition;
performing a thermal treatment to form a metal silicide layer at the junctions between the metallic layer and the source/drain region and between the metallic layer and the gate electrode; and
removing the first protective layer, the second protective layer and any unreacted metallic layer.

11. The method of claim 10, wherein the step of forming the metallic layer includes depositing cobalt.

12. The method of claim 11, wherein the step of forming the first protective layer includes depositing titanium nitride.

13. The method of claim 11, wherein the first protective layer has a thickness between about 100 Å to 200 Å.

14. The method of claim 10, wherein the step of forming the second protective layer includes depositing titanium nitride.

15. The method of claim 14, wherein the second protective layer has a thickness between about 100 Å to 200 Å.

16. The method of claim 10, wherein the step of forming the metallic layer includes performing a DC magnetron sputtering.

17. The method of claim 10, wherein the metallic layer, the first protective layer and the second protective layer are formed in the same reaction chamber, and the firstprotective layer is formed in a chemical vapor deposition chamber inside the reaction chamber.

18. The method of claim 10, wherein the thermal treatment includes a rapid thermal process.

19. The method of claim 10, wherein after the step of removing the protective layers and the unreacted metal, further includes performing a post thermal treatment.

20. The method of claim 19, wherein the post thermal treatment includes a rapid thermal process.
